(19) United States
(12) Patent Application Publication
(10) Pub. No.: US 2011/0109392 A1
(43) Pub. Date: May 12, 2011

(54) LOW NOISE AMPLIFIER

(75) Inventors: Jang Hyun PARK, Seoul (KR); Chang Sun Kim, Seoul (KR); Yea Chul Roh, Seongnam (KR); Tae-Yeoul Yun, Seoul (KR); Hyun-kyu Park, Seoul (KR); Ji-Young Lee, Seoul (KR)

(73) Assignees: Electronics and Telecommunications Research Institute, Daejeon (KR); Industry-University Cooperation Foundation Hanyang University, Seoul (KR)

(21) Appl. No.: 12/907,925

(22) Filed: Oct. 19, 2010

(30) Foreign Application Priority Data
Nov. 9, 2009 (KR) 10-2009-0107542
Apr. 8, 2010 (KR) 10-2010-0032294

(51) Int. Cl. H03F 1/34

(52) U.S. Cl. 330/293

(57) ABSTRACT

Provided is a Low Noise Amplifier (LNA). Embodiments of the present invention provide LNAs including: a common gate amplifier circuit configure to amplify a signal of an input node to which an Alternating Current (AC) component is provided and transfer the amplified signal to an amplifier node; and a negative-feedback amplifier circuit configured to amplify a signal of the amplifier node, transfer the amplified signal to an output node, wherein the negative-feedback amplifier circuit includes a feedback capacitor and a feedback inductor connected in series between the amplifier node and the output node to form a negative feedback. the LNA of the present invention forms a negative feedback exclusive of a feedback resistance, such that a broad frequency bandwidth is obtained and noise and heat are reduced.

### CROSS-REFERENCE TO RELATED APPLICATIONS

This U.S. non-provisional patent application claims priority under 35 U.S.C. §119 of Korean Patent Application Nos. 10-2010-0032294, filed on Apr. 8, 2010, and 10-2009-0107542, filed on Nov. 9, 2009, the entire contents of which are hereby incorporated by reference.

### BACKGROUND OF THE INVENTION

The present invention disclosed herein relates to a low noise amplifier (LNA).

In general, an LNA (Low Noise Amplifier) amplifies a weak signal received through an antenna of a wireless device such as a portable TV, minimizing the effect of noise and selecting a desired frequency band. Especially, an LNA that may be commonly used for a variety of frequency bands is required because portable TV standards of each country adopt a variety of frequency bands recently.

In order to improve reception sensitivity of a receiver, noise needs to be designed minimally if possible. The noise of a receiver is mostly determined by an LNA at a front end of the receiver, such that maintaining an appropriate linearity and gain and minimizing noise are the most significant issue when the LNA is designed.

Moreover, since most of terminals need to be matched to about 50Ω, selecting an appropriate size of an input terminal Complementary Metal Oxide (CMOS) device is required by considering current consumption.

In a case of a typical CMOS LNA, since input impedance is capacitive, input matching is difficult and since noise and power matching points are considerably far from each other, input impedance is designed using a source inductor to optimize the two matching points.

In relation to this LNA, since noise characteristics determine entire performance of a receiver, the noise and signal distortion of the LNA need to be suppressed to the maximum and impedance matching of an input terminal and an output terminal of an amplifier is used for the maximum signal transmission.

### SUMMARY OF THE INVENTION

The present invention provides a Low Noise Amplifier (LNA) for expanding a bandwidth and reducing noise and heat. Embodiments of the present invention provide LNAs including: a common gate amplifier circuit configure to amplify a signal of an input node to which an Alternating Current (AC) component is provided and transfer the amplified signal to an amplifier node; and a negative feedback amplifier circuit configured to amplify a signal of the amplifier node, transfer the amplified signal to an output node, wherein the negative feedback amplifier includes a feedback capacitor and a feedback inductor connected in series between the amplifier node and the output node to form a negative feedback.

In some embodiments, the common gate amplifier circuit may include: an input capacitor connected between an input terminal for receiving the input signal and the input node; a bias inductor connected between the input node and a ground terminal; and a first transistor including a source connected to the input node, a drain connected to the amplifier node, and a gate to which a bias voltage is provided, wherein the amplifier node receives a first power supply voltage and an AC component of a signal of the output node is an output signal.

In other embodiments, the negative-feedback amplifier circuit may include: a second transistor including a source connected to the ground terminal, a drain connected to the output node, and a gate connected to the amplifier node; an output capacitor connected between the output node and an output terminal; and a load connected between a power supply voltage terminal for providing a second power supply voltage and the output node.

In still other embodiments, the first and second transistors may be Metal Oxide Semiconductor (MOS) transistors.

In even other embodiments, the first and second transistor may be Bipolar Junction Transistors (BJTs).

In yet other embodiments, the first and second transistor may be GaAs Metal Semiconductor Field Effect Transistors (MESFETs).

In further embodiments, the second power supply voltage may be higher than the first power supply voltage.

In other embodiments of the present invention, LNAs include: a first transistor including a source connected to an input node, a drain connected to a first amplifier node, and a gate connected to a first bias terminal for providing a first bias voltage; a second transistor including a source connected to a ground terminal, a drain connected to a second amplifier node, and a gate connected to the first amplifier node; an input capacitor connected between an input terminal for receiving an input signal and the input node; a feedback capacitor having one end connected to the first amplifier node; a first bias inductor connected between the input node and the ground terminal; a second bias inductor connected between the amplifier node and a second bias terminal for providing a second bias voltage; a feedback inductor connected between the other end of the feedback capacitor and the second amplifier node; a current reused circuit connected between the second amplifier node and a third amplifier node and performing amplification of a similar level as or a higher level than before as reducing a current amount that flows through the second transistor; and a buffer circuit having a source follower structure to output a signal of the third amplifier node.

In some embodiments, the current reused circuit may include: a third transistor including a source connected to a ground node, a drain connected to the third amplifier node, and a gate connected to a bias node; a first current reused capacitor connected between the ground node and the ground terminal; a second current reused capacitor connected between the ground node and the bias node; a third bias inductor connected between the bias node and a third bias terminal for providing a third bias voltage; and a current reused inductor connected between the second amplifier node and the ground node.

In other embodiments, the buffer circuit may include: a fourth transistor including a source connected to an output node and a drain connected to the power supply voltage terminal; a first load inductor connected between the third amplifier node and a power supply terminal; a second load inductor connected between the third amplifier node and a gate of the fourth transistor; a bias current source connected between the output node and the ground terminal; and an output capacitor connected between the output node and an output terminal.

### BRIEF DESCRIPTION OF THE DRAWINGS

The accompanying drawings are included to provide a further understanding of the present invention, and are incorporated in and constitute a part of this specification. The drawings illustrate exemplary embodiments of the present invention and, together with the description, serve to explain principles of the present invention. In the drawings:

FIG. 1 is a view illustrating a typical low noise amplifier (LNA) 10;

FIG. 2 is a view illustrating an LNA 100 according to a first embodiment of the present invention;

FIG. 3 is a view illustrating an LNA 200 according to a second embodiment of the present invention;

FIG. 4 is a graph illustrating a gain of an LNA according to an embodiment of the present invention; and

FIG. 5 is a graph illustrating noise characteristics of an LNA according to an embodiment of the present invention.

### DETAILED DESCRIPTION OF PREFERRED EMBODIMENTS

Some embodiments of the present invention will now be described hereinafter with reference to the accompanying drawings, in which embodiments of the invention are shown. This invention may, however, be embodied in many different forms and should not be construed as limited to the embodiments set forth herein. Rather, these embodiments are provided so that this disclosure will be thorough and complete, and will fully convey the scope of the invention to those skilled in the art. Like numbers refer to like items throughout.

It will be understood that when an item is referred to as being “connected” or “coupled” to another item, it can be directly connected or coupled to the other item or intervening items may be present. In contrast, when an item is referred to as being “directly connected” or “directly coupled” to another item, there are no intervening items present. As used herein, the term “and/or” includes any and all combinations of one or more of the associated listed items and may be abbreviated as “/”.

It will be understood that, although the terms first, second, etc. may be used herein to describe various items, these items should not be limited by these terms. These terms are only used to distinguish one item from another. For example, a “first” item could be termed a “second” item, and, similarly, a “second” item could be termed a “first” item without departing from the teachings of the disclosure.

The terminology used herein is for the purpose of describing particular embodiments only and is not intended to be limiting of the invention. As used herein, the singular forms “a”, “an” and “the” are intended to include the plural forms as well, unless the context clearly indicates otherwise. It will be further understood that the terms “comprises” and/or “comprising,” or “includes” and/or “including” when used in this specification, specify the presence of stated items or operations but do not preclude the presence or addition of one or more other items or operations.

Unless otherwise defined, all terms (including technical and scientific terms) used herein have the same meaning as commonly understood by one of ordinary skill in the art to which this invention belongs. It will be further understood that terms, such as those defined in commonly used dictionaries, should be interpreted as having a meaning that is consistent with their meaning in the context of the relevant art and/or the present application, and will not be interpreted in an idealized or overly formal sense unless expressly so defined herein.

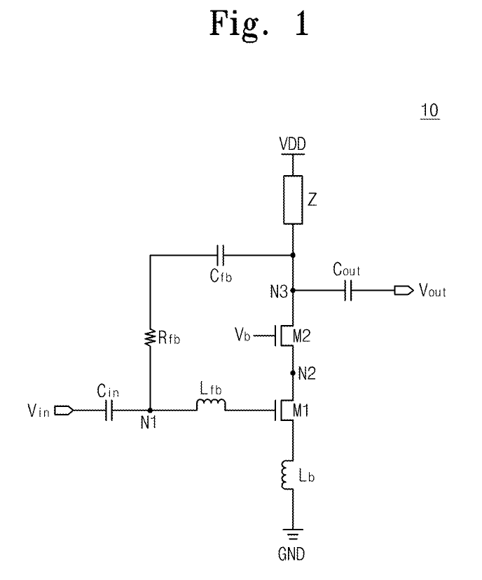

FIG. 1 is a view illustrating a typical low noise amplifier (LNA) 10. Referring to FIG. 1, the LNA 10 includes capacitors Cᵢₙ, C_{fb}, and Cₒᵤₜ, first and second Metal Oxide Semiconductor (MOS) transistors M1 and M2, first and second inductors L_{fb} and L_{b}, a feedback resistor R_{fb}, and an output load Z.

The first MOS transistor M1 includes a drain connected to a second node N2 and a source connected to the second inductor Lb.

The second MOS transistor M2 includes a drain connected to a third node N3, a source connected to a second node N2, and a gate for receiving a bias voltage V_{b}.

The first inductor Lfb is connected to a first node N1 and a gate of the first MOS transistor M1. The first inductor L_{fb} removes an imaginary part of impedance with respect to an input signal Vᵢₙ using an inductance sum of the first and second inductors L_{fb} and L_{b}. The second inductor L_{b} is connected to the source of the first MOS transistor M1.

A generated parasite capacitance Cgs and a transconductance gm generated in parallel thereto in the first MOS transistor M1 generate a real part of impedance through a combination of an inductance component of the second inductor Lb.

The first inductor L_{fb}, second inductor L_{b}, and first MOS transistor M1 remove an imaginary part of the impedance and generates the impedance of a real part. In such a way, impedance matching is completed.

Furthermore, the second MOS transistor M2 having a gate to which a bias voltage V_{b} is applied amplifies an input signal Vᵢₙ. Moreover, a negative feedback including a feedback capacitor C_{fb} and a feedback resistor R_{fb} for broadband characteristics is formed in the drain of the second MOS transistor M2.

Here, the feedback capacitor C_{fb} prevents the leakage of a Direct Current (DC) bias that is applied to both ends thereof. Moreover, the feedback resistor R_{fb} has a value of hundreds Ω to thousands Ω and determines an amount of a negative feedback signal. The typical LNA 10 amplifies and outputs an input signal Vin through impedance matching and a negative feedback using the common first inductor Lfb.

The typical LNA 10 includes a feedback resistor R_{fb} on a signal path. However, this resistance component causes noise and heat. Accordingly, if the typical LNA 10 is used, performance may be deteriorated or an overall noise component may be increased.

However, an LNA according to the present invention removes a feedback resistance in a negative feedback, such that the matching effect of a broad frequency band may be obtained and noise and heat may be reduced.

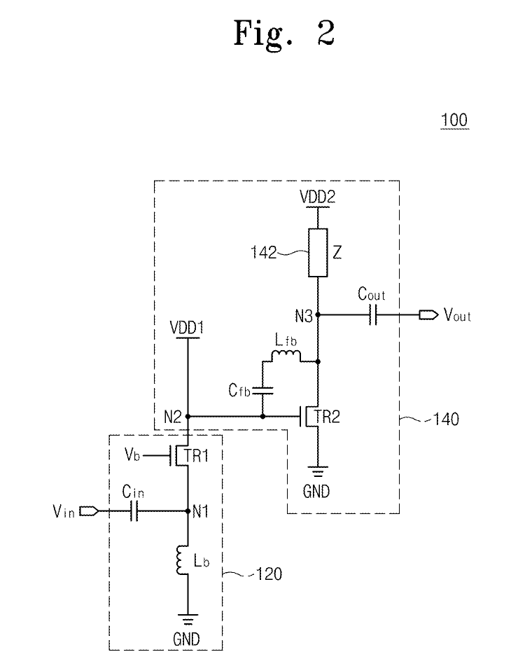

FIG. 2 is a view illustrating an LNA 100 according to a first embodiment of the present invention. Referring to FIG. 2, the LNA 100 includes a common gate amplifier circuit 120 and a negative-feedback amplifier circuit 140. The negative-feedback amplifier circuit 140 does not include a resistance component in a negative feedback.

The common gate amplifier circuit 120 amplifies a signal of a first node N1 and transmits the amplified signal to a second node N2. Here, the first node N1 receives an Alternating Current (AC) component of an input signal Vᵢₙ. Here, the first node N1 is an input node and the second node N2 is an amplifier node. The common gate amplifier circuit 120 includes an input capacitor Cᵢₙ, a bias inductor L_{b}, and a first transistor TR1. The common gate amplifier circuit 120 is realized with a common gate stage used a gate as Alternating Current (AC) ground and a source as input terminal. The input capacitor Cᵢₙ is connected between an input terminal and the first node N1. The input capacitor Cᵢₙ receives an input signal Vᵢₙ. The input capacitor Cᵢₙ transmits to the first node N1 an AC component exclusive of a DC component of the input signal Vᵢₙ.

The bias inductor L_{b} is connected between the first node N1 and a ground terminal GND. The bias inductor L_{b} is used for input impedance matching and prevents an AC component of the input signal Vᵢₙ from leaking into ground.

The first transistor TR1 includes a source connected to the first node N1, a drain connected to the second node N2, and a gate for receiving a bias voltage V_{b}. Here, the first transistor TR1 may be realized with one of a Metal-Oxide-Semiconductor Field Effect Transistor (MOSFET), a Bipolar Junction Transistor (BJT), and a GaAs Metal Semiconductor Field Effect Transistor (MESFET).

The input signal Vᵢₙ is applied to the source of the first transistor TR1. Here, an impedance value viewed from the source of the first transistor TR1 is about 1/gm. Here, gm is a transconductance value of the first transistor TR1.

The common gate amplifier circuit 120 has a source for receiving the input signal Vᵢₙ, such that the impedance matching and noise of a broadband may be minimized.

The negative-feedback amplifier circuit 140 amplifies a signal of the second node N2 and transmits the amplified signal to the third node N3, and forms a negative feedback in the second node N2 and the third node N3. Here, the third node N3 is an output node. The negative feedback does not include a resistance component. The negative-feedback amplifier circuit 140 includes a second transistor TR2, an output capacitor Cₒᵤₜ, a feedback capacitor C_{fb}, a feedback inductor L_{fb}, and a load 142. Especially, the negative-feedback amplifier circuit 140 includes a feedback capacitor C_{fb} and a feedback inductor L_{fb}, which are connected in series, to form a negative feedback.

The second transistor TR2 includes a source connected to a ground terminal GND, a drain connected to a third node N3, and a gate connected to the second node N2. Here, the second transistor TR2 may be realized with one of a MOSFET, a BJT, and a GaAs MESFET. Here, the second node N2 receives a first power supply voltage VDD1 (e.g., about 1.0 V). In another embodiment, the second node N2 may receives the first power supply voltage VDD1.

The output capacitor Cₒᵤₜ is connected between the third node N3 and an output terminal and outputs an AC component after extracting a DC component from a signal of the third node N3. The output capacitor Cₒᵤₜ prevents the DC component from leaking into the output terminal.

In order to form a negative feedback, the feedback capacitor C_{fb} and the feedback inductor L_{fb} are connected in series between the second node N2 and the third node N3. That is, one end of the feedback capacitor C_{fb} is connected to the second node N2 and the other end of the feedback capacitor C_{fb} is connected to one end of the feedback inductor L_{fb} and other end of the feedback inductor L_{fb} is connected to the third node N3.

The load 142 is connected between a power supply voltage terminal and the third node N3. Here, the power supply voltage terminal receives a second power supply voltage VDD2 (e.g., about 1.8 V). An output signal Vₒᵤₜ is outputted from the load 142.

The negative-feedback amplifier circuit 140 expands a bandwidth. The negative-feedback amplifier circuit 140 improves the stability of a broadband amplifier and is advantageous for bandwidth expansion. Furthermore, the negative-feedback amplifier circuit 140 forms a negative feedback exclusive of a resistance component to expand a bandwidth and reduce noise and heat.

The typical LNA 10 of FIG. 1 forms a negative feedback having the feedback resistance R_{fb}. However, the feedback resistance R_{fb} causes thermal noise (4kTR_{fb}, T is an absolute temperature). On the contrary, the LNA 100 of the present invention forms a negative feedback exclusive of a feedback resistance, such that a broad frequency bandwidth is obtained and noise and heat are reduced.

The present invention may further add a current reused technique to improve low power characteristics. The current reused technique reduces a current consumption of main amplification and improves conversion gain.

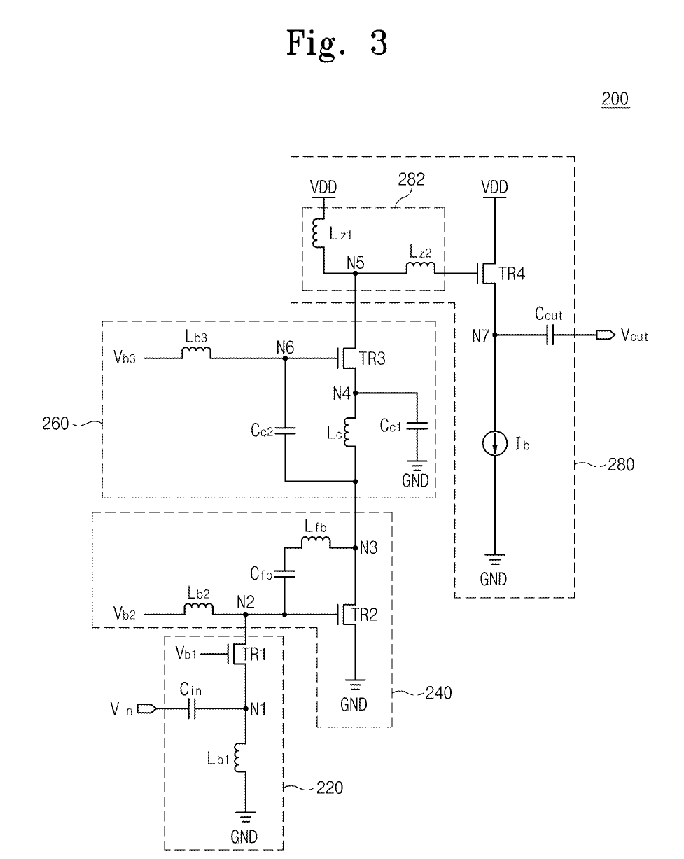

FIG. 3 is a view illustrating an LNA 200 according to a second embodiment of the present invention. Referring to FIG. 3, the LNA 200 includes a common gate amplifier circuit 220, a negative feedback amplifier circuit 240, a current reused circuit 260, and a buffer circuit 280.

The common gate amplifier circuit 220 is realized identical to the common gate amplifier circuit 120 of FIG. 2. The common gate amplifier circuit 220 includes an input capacitor Cᵢₙ, a first bias inductor L_{b1}, and a first transistor TR1.

The input capacitor Cᵢₙ is connected between an input terminal and a first node N1. Here, the first node N1 is an input node. The input capacitor Cᵢₙ, receives an input signal Vᵢₙ. The input capacitor Cᵢₙ prevents a DC component of the input signal Vᵢₙ from flowing into the first node N1.

A first bias inductor L_{b1} is connected between the first node N1 and the ground terminal GND. The first bias inductor L_{b1} is used for input impedance matching and prevents an AC component of the input signal Vᵢₙ from leaking into the ground.

The first transistor TR1 includes a source connected to the first node N1, a drain connected to a second node N2, and a gate connected to a first bias terminal for receiving a first bias voltage V_{b1}. Here, the second node N2 is a first amplifier node. Here, the first transistor TR1 may be realized with one of a MOSFET, a BJT, and a GaAs MESFET.

The input signal Vᵢₙ is applied to the source of the first transistor TR1. Here, an impedance value viewed from the source of the first transistor TR1 may be approximated into about 1/gm1. Here, gm1 is a transconductance value of the first transistor TR1.

The common gate amplifier circuit 220 minimizes impedance matching and noise of a broadband by providing the input signal Vᵢₙ to the source of the first transistor TR1.

The negative-feedback amplifier circuit 240 includes a second transistor TR2, a feedback capacitor C_{fb}, a feedback inductor L_{fb}, and a second bias inductor L_{b2}. Especially, the negative-feedback amplifier circuit 240 includes a feedback capacitor C_{fb} and a feedback inductor L_{fb}, connected in series, to form a negative feedback.

The second transistor TR2 includes a source connected to a ground terminal GND, a drain connected to a third node N3, and a gate connected to the second node N2. Here, the third node N3 is a second amplifier node. Here, the second transistor TR2 may be realized with one of a MOSFET, a BJT, and a GaAs MESFET.

The feedback capacitor C_{fb} and the feedback inductor L_{fb} are connected in series between the second node N2 and the third node N3 to form a negative feedback.

The second bias inductor L_{b2} is connected between a second bias terminal for receiving a second bias voltage V_{b2} and the second node N2. The second bias inductor L_{b2} prevents an AC component of signal transferred to the second node N2 from leaking into the second bias terminal.

The negative-feedback amplifier circuit 220 expands a bandwidth through a negative feedback of an output signal.

The current reused circuit 260 is connected between the third node N3 and a fifth node N5. The current reused circuit 260 reduces current consumption necessary for main amplification and performs amplification of a similar level as or a higher level than before. Here, the fifth node N5 is a third amplifier node. Here, current necessary for main amplification flows through the second transistor TR2 of the negative-feedback amplifier circuit 240. That is, the current reused circuit 260 reduces a current amount flowing through the second transistor TR2 and performs amplification of a similar level as or a higher level than before. The current reused circuit 260 includes a third transistor TR3, first and second current reused capacitors C_{c1} and C_{c2}, a current reused inductor L_{c}, and a third bias inductor L_{b3}.

The third transistor TR3 amplifies a signal of the third node N3 and outputs the amplified signal to the fifth node N5. The third transistor TR3 includes a source connected to the fourth node N4, a drain connected to the fifth node N5, and a gate connected to a sixth node N6. Here, the second transistor TR2 may be realized with one of a MOSFET, a BJT, and a GaAs MESFET.

The first current reused capacitor C_{c1} is connected between the forth node N4 and a ground terminal GND. The second current reused capacitor C_{c2} is connected between the third node N3 and the sixth node N6. The current reused inductor L_{c} is connected between the third node N3 and the fourth node N4.

The third bias inductor L_{b3} is connected between a third bias terminal for receiving the third bias voltage V_{b3} and the sixth node N6. The third bias inductor L_{b3} prevents an AC component of a signal of the sixth node N6 from leaking into the third bias terminal.

The current reused circuit 240 amplifies a signal of the third node N3 by additional about 1/gm2. Here, gm2 is a currentconductance value of the third transistor TR3.

The buffer circuit 280 is connected between the fifth node N5 and an output terminal and is realized with a source follower structure. The buffer circuit 280 includes a load 282, a forth transistor TR4, a bias current source I_{b}, and an output capacitor Cₒᵤₜ.

The load 282 includes first and second load inductors L_{z1} and L_{z2}. The first load inductor L_{z1} is connected between the power source voltage terminal VDD and the fifth node N5. The second load inductor L_{z2} is connected between the fifth node N5 and a gate of the fourth transistor TR4.

The fourth transistor TR4 includes a source connected to a seventh node N7 and a drain connected to a power source voltage terminal VDD. Herein, the seventh node N7 is an output node. Here, the fourth transistor TR4 may be realized with one of a MOSFET, a BJT, and a GaAs MESFET.

The bias current source I_{b} is connected between the seventh node N7 and a ground terminal GND.

The output capacitor Cₒᵤₜ is connected between the seventh node N7 and the output terminal and outputs as an output signal Vₒᵤₜ only an AC component after extracting a DC component from a signal transferred to the seventh node N7.

The buffer circuit 280 transfers a signal of the fifth node N5 as it is to the seventh node N7 through a source follower.

The LNA 200 of the present invention may obtains high gain and reduce current consumption through the current reused circuit 260.

Accordingly, the LNA 200 obtains high gain, expands a bandwidth, and reduces noise and heat.

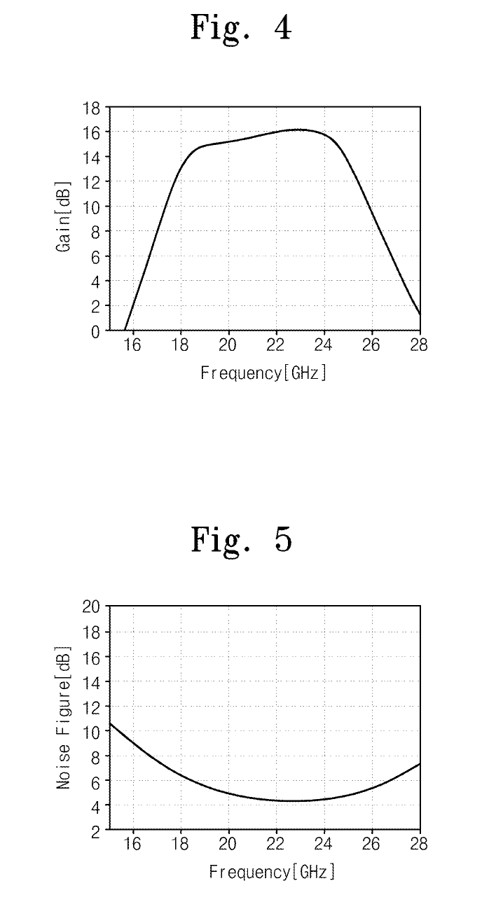

FIG. 4 is a graph illustrating a gain of an LNA according to an embodiment of the present invention. Referring to FIG. 4, about −3 dB bandwidth of a gain is about 18 GHz to about 25 GHz, i.e., a K-band area. Accordingly, the LNA of the present invention obtains a high gain and broad bandwidth.

FIG. 5 is a graph illustrating noise characteristics of an LNA according to an embodiment of the present invention. Referring to FIG. 5, the LNA has an overall small noise figure (about 4 dB to about 10 dB).

The LNA according to the present invention realizes a negative feedback exclusive of a resistance component, such that a bandwidth may be expanded and noise and heat may be reduced.

The above-disclosed subject matter is to be considered illustrative, and not restrictive, and the appended claims are intended to cover all such modifications, enhancements, and other embodiments, which fall within the true spirit and scope of the present invention. Thus, to the maximum extent allowed by law, the scope of the present invention is to be determined by the broadest permissible interpretation of the following claims and their equivalents, and shall not be restricted or limited by the foregoing detailed description.

What is claimed is:

1. A Low Noise Amplifier (LNA) comprising:
a common gate amplifier circuit configure to amplify a signal of an input node to which an Alternating Current (AC) component is provided and transfer the amplified signal to an amplifier node; and
a negative-feedback amplifier circuit configured to amplify a signal of the amplifier node, transfer the amplified signal to an output node,
wherein the negative-feedback amplifier includes a feedback capacitor and a feedback inductor connected in series between the amplifier node and the output node to form a negative feedback.

2. The LNA of claim 1, wherein the common gate amplifier circuit comprises:
an input capacitor connected between an input terminal for receiving the input signal and the input node;
a bias inductor connected between the input node and a ground terminal; and
a first transistor including a source connected to the input node, a drain connected to the amplifier node, and a gate to which a bias voltage is provided,
wherein the amplifier node receives a first power supply voltage and an AC component of a signal of the output node is an output signal.

3. The LNA of claim 2, wherein the negative-feedback amplifier circuit comprises:
a second transistor including a source connected to the ground terminal, a drain connected to the output node, and a gate connected to the amplifier node;
an output capacitor connected between the output node and an output terminal; and
a load connected between a power supply voltage terminal for providing a second power supply voltage and the output node.

4. The LNA of claim 3, wherein the first and second transistors are Metal Oxide Semiconductor (MOS) transistors.

5. The LNA of claim 3, wherein the first and second transistor are Bipolar Junction Transistors (BJTs).

6. The LNA of claim 3, wherein the first and second transistor are GaAs Metal Semiconductor Field Effect Transistors (MESFETs).

7. The LNA of claim 3, wherein the second power supply voltage is higher than the first power supply voltage.

8. An LNA comprising:
a first transistor including a source connected to an input node, a drain connected to a first amplifier node, and a gate connected to a first bias terminal for providing a first bias voltage;
a second transistor including a source connected to a ground terminal, a drain connected to a second amplifier node, and a gate connected to the first amplifier node;
an input capacitor connected between an input terminal for receiving an input signal and the input node;
a feedback capacitor having one end connected to the first amplifier node;
a first bias inductor connected between the input node and the ground terminal;
a second bias inductor connected between the amplifier node and a second bias terminal for providing a second bias voltage;
a feedback inductor connected between the other end of the feedback capacitor and the second amplifier node;
a current reused circuit connected between the second amplifier node and a third amplifier node and performing amplification of a similar level as or a higher level than before as reducing a current amount that flows through the second transistor; and
a buffer circuit having a source follower structure to output a signal of the third amplifier node.

9. The LNA of claim 8, wherein the current reused circuit comprises:
a third transistor including a source connected to a ground node, a drain connected to the third amplifier node, and a gate connected to a bias node;
a first current reused capacitor connected between the ground node and the ground terminal;
a second current reused capacitor connected between the ground node and the bias node;
a third bias inductor connected between the bias node and a third bias terminal for providing a third bias voltage; and
a current reused inductor connected between the second amplifier node and the ground node.

10. The LNA of claim 9, wherein the buffer circuit comprises:
a fourth transistor including a source connected to an output node and a drain connected to the power supply voltage terminal;
a first load inductor connected between the third amplifier node and a power supply terminal;
a second load inductor connected between the third amplifier node and a gate of the fourth transistor;
a bias current source connected between the output node and the ground terminal; and
an output capacitor connected between the output node and an output terminal.
